(19) United States
(12) Patent Application Publication
(10) Pub. No.: US 2025/0253240 A1
(43) Pub. Date: Aug. 7, 2025

(54) THREE-DIMENSIONAL MEMORY DEVICE HAVING SUPPORT PATTERNS

(71) Applicant: SK hynix Inc., Gyeonggi-do (KR)

(72) Inventors: Byung Soo PARK, Gyeonggi-do (KR); Jee Hyun KIM, Gyeonggi-do (KR); Yu Jin KWON, Gyeonggi-do (KR); Jeong Seob OH, Gyeonggi-do (KR)

(21) Appl. No.: 18/766,680

(22) Filed: Jul. 9, 2024

(30) Foreign Application Priority Data
Feb. 7, 2024 (KR) 10-2024-0018660

(51) Int. Cl. H01L 23/528; H10B 43/10; H10B 43/27

(52) U.S. Cl. CPC H01L 23/5283; H01L 23/528; H10B 43/10; H10B 43/27

(57) ABSTRACT

A three-dimensional memory device includes a stack structure including first and second tier stacks stacked on a substrate, each of the first and second tier stacks including a plurality of electrode layers and a plurality of interlayer insulating layers alternately stacked; a connection contact penetrating at least partially the stack structure; and a plurality of support patterns each including a first tier support penetrating the first tier stack and a second tier support penetrating the second tier stack. The plurality of support patterns include first support patterns adjacent to the connection contact. In two first support patterns among the first support patterns, which neighbor each other with the connection contact interposed therebetween, a gap between first tier supports is smaller than a gap between second tier supports.

### CROSS-REFERENCE TO RELATED APPLICATION

The present application claims priority under 35 U.S.C. § 119(a) to Korean Patent Application No. 10-2024-0018660 filed on Feb. 7, 2024, which is incorporated herein by reference in its entirety.

### BACKGROUND

### 1. Technical Field

Various embodiments of the present disclosure generally relate to a semiconductor technology, and more particularly, to a three-dimensional memory device which has support patterns.

### 2. Related Art

A three-dimensional memory device having memory cells which are three-dimensionally arranged has been proposed. The three-dimensional memory device has advantages in that a larger capacity may be realized within the same area by increasing the number of stacks through stacking memory cells in a vertical direction, thereby providing high performance and excellent power efficiency. In the three-dimensional memory device, support patterns are used to increase the structural stability of a stack structure.

### SUMMARY

In an embodiment of the present disclosure, a three-dimensional memory device may include a stack structure including first and second tier stacks which are stacked on a substrate and each of which includes a plurality of electrode layers and a plurality of interlayer insulating layers alternately stacked; a connection contact penetrating the stack structure; and a plurality of support patterns each including a first tier support which penetrates the first tier stack and a second tier support which penetrates the second tier stack, wherein the plurality of support patterns include first support patterns which neighbor the connection contact, and wherein in two first support patterns among the first support patterns, which neighbor each other with the connection contact interposed therebetween, a gap between first tier supports is smaller than a gap between second tier supports.

In an embodiment of the present transaction, a three-dimensional memory device may include a stack structure including first, second, third and fourth tier stacks which are stacked on a substrate and each of which includes a plurality of electrode layers and a plurality of interlayer insulating layers alternately stacked; a connection contact including a lower contact which penetrates the first and second tier stacks and an upper contact which penetrates the third and fourth tier stacks to be connected to the lower contact; and a plurality of support patterns each including a first tier support which penetrates the first tier stack, a second tier support which penetrates the second tier stack, a third tier support which penetrates the third tier stack, and a fourth tier support which penetrates the fourth tier stack, wherein the plurality of support patterns include first support patterns which neighbor the connection contact, and wherein in two first support patterns among the first support patterns, which neighbor each other with the connection contact interposed therebetween, a gap between first tier supports is smaller than a gap between second tier supports, and a gap between third tier supports is smaller than a gap between fourth tier supports.

### BRIEF DESCRIPTION OF THE DRAWINGS

FIG. 1 is a cross-sectional view illustrating a three-dimensional memory device according to an embodiment of the present disclosure.

FIG. 2 is a diagram illustrating a connection contact and first support patterns of FIG. 1.

FIG. 3 is a diagram illustrating first and second support patterns of FIG. 1.

FIG. 4 is a plan view illustrating cell plugs and second tier supports of the first and second support patterns in the three-dimensional memory device according to an embodiment of the present disclosure.

FIGS. 5 and 6 are plan views illustrating cell plugs and first tier supports of the first and second support patterns in the three-dimensional memory device according to an embodiment of the present disclosure.

FIG. 7 is a cross-sectional view of a three-dimensional memory device according to an embodiment of the present disclosure.

FIG. 8 is a diagram illustrating a connection contact and first support patterns of FIG. 7.

FIG. 9 is a diagram illustrating first and second support patterns of FIG. 7.

FIG. 10 is a cross-sectional view illustrating a three-dimensional memory device according to an embodiment of the present disclosure.

FIGS. 11 to 16 are views showing a method of fabricating a three-dimensional memory device according to an embodiment of the present disclosure.

### DETAILED DESCRIPTION

Hereinafter, embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the present disclosure, there may be terms used like first, second, A, B, (a), and (b). These are solely for the purpose of differentiating one component from another component but do not limit the substances, order, sequence or number of the components.

In descriptions for the positional relationships of components, in the case where it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “coupled” or “linked” with each other.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information is mentioned, even though there is no separate explicit description, the numerical value or its corresponding information can be interpreted as including an error range that may be caused by various factors (for example, a process variable, an internal or external shock, noise, etc.).

Various embodiments of the present invention are directed to a three-dimensional memory device which has improved support patterns.

According to embodiments of the present disclosure, it is possible to provide a three-dimensional memory device which has support patterns of a multi-tier structure.

Hereinafter, various embodiments of the present disclosure will be described in detail with reference to the accompanying drawings.

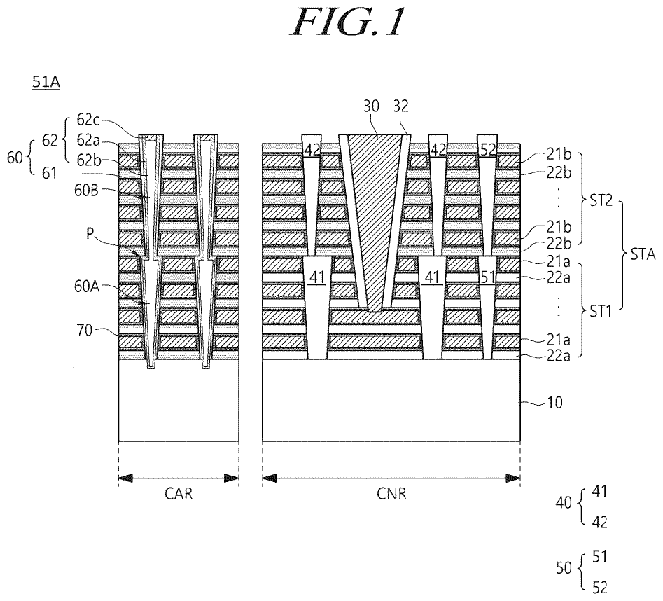

FIG. 1 is a cross-sectional view of a three-dimensional memory device according to an embodiment of the present disclosure.

Referring to FIG. 1, the three-dimensional memory device according to an embodiment of the present disclosure includes a stack structure STA disposed on a substrate 10.

The stack structure STA may include a first tier stack ST1 disposed on the substrate 10 and a second tier stack ST2 disposed on the first tier stack ST1.

The first tier stack ST1 may include a plurality of first electrode layers 21a and a plurality of first interlayer insulating layers 22a which are alternately stacked. As in the illustrated embodiment, the lowermost layer of the first stack ST1 may be a first interlayer insulating layer 22a and the uppermost layer of the first stack ST1 may be a first electrode layer 21a. Although not illustrated, each of the lowermost layer of the first stack and the uppermost layer of the first stack may be a first interlayer insulating layer. The second tier stack ST2 may include a plurality of second electrode layers 21b and a plurality of second interlayer insulating layers 22b which are alternately stacked. As in the illustrated embodiment, the lowermost layer of the second stack ST2 may be a second interlayer insulating layer 22b and the uppermost layer of the second stack ST2 may be a second electrode layer 21b. Although not illustrated, each of the lowermost layer of the second stack and the uppermost layer of the second stack may be a second interlayer insulating layer.

The first and second electrode layers 21a and 21b may include a conductive material. For example, the first and second electrode layers 21a and 21b may include tungsten (W). Also, for example, the first and second interlayer insulating layers 22a and 22b may include silicon oxide.

The first and second electrode layers 21a and 21b may include word lines and select lines. The select lines may include a drain select line and a source select line.

A connection contact 30 may vertically penetrate at least a portion of the stack structure STA. For example, in the illustrated embodiment, the connection contact 30 fully penetrates through the second stack ST2 and passes through only some of the layers of the first stack ST1. The stack structure STA may include a cell region CAR and a connection region CNR, and the connection contact 30 may vertically penetrate the connection region CNR of the stack structure STA. The connection contact 30 may include a conductive material. For example, the connection contact 30 may include tungsten (W), but the embodiments are not limited thereto.

Generally, the connection contact 30 may partially penetrate the stack structure STA and be electrically connected to one of the first and second electrode layers 21a and 21b. For example, as illustrated in FIG. 1, the lower end of the connection contact 30 may be located at a first electrode layer 21a, and the connection contact 30 may be electrically connected to the first electrode layer 21a. Although not illustrated, the lower end of the connection contact 30 may be located at a second electrode layer 21b, and the connection contact 30 may be electrically connected to the second electrode layer 21b. In an embodiment, although not illustrated, the connection contact 30 may be electrically connected to one of the first and second electrode layers 21a and 21b while completely penetrating the stack structure STA. The connection contact 30 may serve to transmit an operating voltage from a row decoder (not illustrated), to one of the first and second electrode layers 21a and 21b. Although FIG. 1 illustrates only one connection contact 30, a plurality of connection contacts 30 may be provided corresponding to the pluralities of first and second electrode layers 21a and 21b.

Although not illustrated, the connection contact 30 may not be electrically connected to the first and second electrode layers 21a and 21b of the stack structure STA. The connection contact 30 may completely penetrate vertically the stack structure STA, and may serve to electrically connect an upper interconnection (not illustrated) which is provided on the stack structure STA and a lower interconnection (not illustrated) which is provided under the substrate 10.

The connection contact 30 has a tapered shape whose dimension (e.g., its width) decreases as a distance to the substrate 10 decreases. A sidewall insulating layer 32 may be disposed on the side surface of the connection contact 30 to electrically separate the connection contact 30 and the first and second electrode layers 21a and 21b of the stack structure STA.

Support patterns 40 (41, 42) and 50 (51, 52) may vertically penetrate the stack structure STA. The support patterns 40 and 50 may penetrate the connection region CNR of the stack structure STA. The support patterns 40 and 50 may serve to support the stack structure STA to prevent the gap between neighboring first and second interlayer insulating layers 22a and 22b from narrowing or neighboring first and second interlayer insulating layers 22a and 22b from sticking together, that is, a stack bending. In addition, the support patterns 40 and 50 may also serve to prevent the stack structure STA from leaning or collapsing.

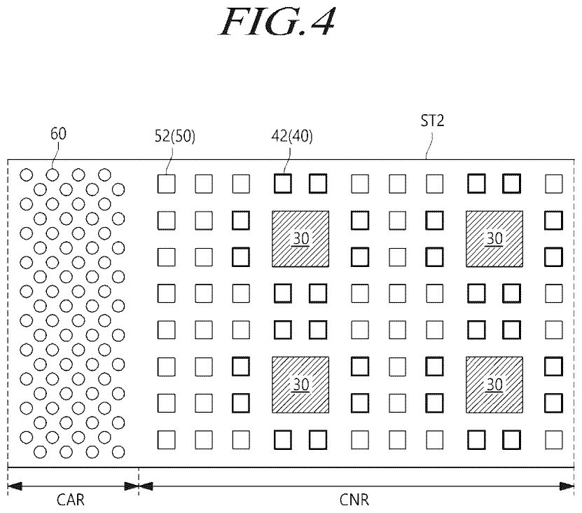

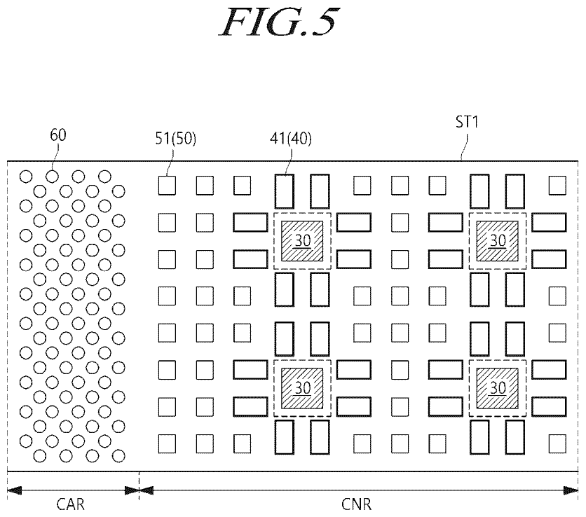

The support patterns 40 and 50 may include first support patterns 40 which neighbor the connection contact 30 and second support patterns 50 which do not neighbor the connection contact 30. Although FIG. 1 illustrates only one second support pattern 50, as will be described later with reference to FIGS. 4 and 5, a plurality of second support patterns 50 may be provided.

The first support pattern 40 includes a first tier support 41 which penetrates the first tier stack ST1 and a second tier support 42 which penetrates the second tier stack ST2. The second support pattern 50 includes a first tier support 51 which penetrates the first tier stack ST1 and a second tier support 52 which penetrates the second tier stack ST2.

In the first support pattern 40, the lower end of the first tier support 41 may be connected to the substrate 10, and the lower end of the second tier support 42 may be connected to the first tier support 41. In the second support pattern 50, the lower end of the first tier support 51 may be connected to the substrate 10, and the lower end of the second tier support 52 may be connected to the first tier support 51.

Each of the first and second tier supports 41 and 42 of the first support pattern 40 and the first and second tier supports 51 and 52 of the second support pattern 50 may have a tapered shape whose dimension (e.g., their width) decreases as a distance to the substrate 10 decreases.

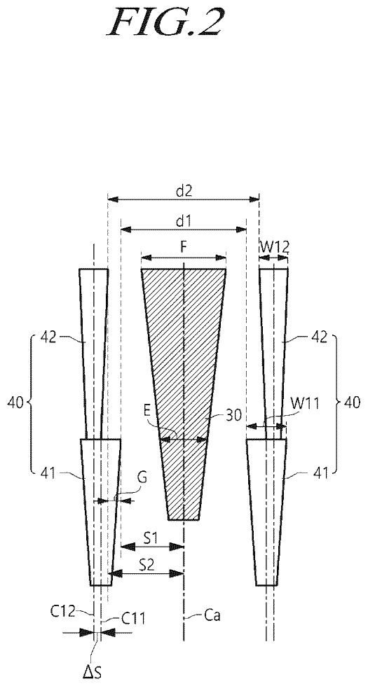

As will be described later with reference to FIG. 2, two first support patterns 40 which neighbor each other with the connection contact 30 interposed therebetween may be configured such that the gap between the first tier supports 41 has a size smaller than the gap between the second tier supports 42.

A plurality of cell plugs 60 may vertically penetrate the cell region CAR of the stack structure STA to extend to the substrate 10. Each cell plug 60 may include a memory pattern 61 and a channel structure 62.

Although not illustrated, the memory pattern 61 may include a tunnel insulating layer, a data storage layer and a first blocking insulating layer. The tunnel insulating layer may extend along the surface of the channel structure 62, and may include an insulating material capable of charge tunneling. The data storage layer may extend along the surface of the channel structure 62 with the tunnel insulating layer interposed therebetween. The data storage layer may include a material layer capable of storing data which is changed, using Fowler-Nordheim tunneling. For example, the data storage layer may include a nitride layer capable of charge trapping, but the embodiments are not limited thereto. The data storage layer may include a phase change material, nanodots, etc. The first blocking insulating layer may extend along the surface of the channel structure 62 with the tunnel insulating layer and the data storage layer interposed therebetween. The first blocking insulating layer may include an insulating material capable of blocking the movement of charges.

The channel structure 62 may include a cell channel layer 62a, a core insulating pattern 62b and a capping pattern 62c. The cell channel layer 62a is used as the channel of a memory cell string. The cell channel layer 62a is disposed on the memory pattern 61, and may be formed of a semiconductor material. For example, the cell channel layer 62a may include silicon. The core insulating pattern 62b and the capping pattern 62c may fill the central region of the channel structure 62. The core insulating pattern 62b may include oxide. The capping pattern 62c may be disposed on the core insulating pattern 62b, and may include a sidewall which is surrounded by the upper end portion of the cell channel layer 62a. The capping pattern 62c may include a doped semiconductor layer which includes at least one of an n-type impurity and a p-type impurity.

The cell plug 60 has a step portion P whose dimension changes discontinuously at the boundary between the first tier stack ST1 and the second tier stack ST2. Each of the cell plugs 60 includes a first portion 60A which vertically penetrates the first tier stack ST1 and a second portion 60B which vertically penetrates the second tier stack ST2. Each of the first portion 60A of the cell plug 60 and the second portion 60B of the cell plug 60 may have a tapered shape whose dimension decreases as a distance to the substrate 10 decreases. The lower end of the second portion 60B of the cell plug 60 may have a dimension smaller than the upper end of the first portion 60A of the cell plug 60. Due to the difference in dimension between the upper end of the first portion 60A of the cell plug 60 and the lower end of the second portion 60B of the cell plug 60, the dimension (e.g., the width) of the cell plug 60 may discontinuously change at the boundary between the first tier stack ST1 and the second tier stack ST1 to form the step portion P.

A second blocking insulating layer 70 may be formed along the surfaces of the first and second electrode layers 21a and 21b. The second blocking insulating layer 70 may include an insulating material which has a higher dielectric constant than the first blocking insulating layer of the memory pattern 61. By way of example, the first blocking insulating layer may include silicon oxide, and the second blocking insulating layer 70 may include a metal oxide such as aluminum oxide. FIG. 2 is a diagram illustrating the connection contact and the first support patterns of FIG. 1.

Referring to FIG. 2, in the two first support patterns 40 which neighbor each other with the connection contact 30 interposed therebetween, the gap between the top surfaces of the first tier supports 41 is d1, and the gap between the top surfaces of the second tier supports 42 is d2, and d1 is smaller than d2. Hence, the two first support patterns 40 which neighbor each other with the connection contact 30 interposed therebetween are configured such that the gap d1 between the first tier supports 41 has a size smaller than the gap d2 between the second tier supports 42.

Also, the gap between the top surface of the first tier support 41 of the first support pattern 40 and the center axis Ca of the connection contact 30 is S1, the gap between the top surface of the second tier support 42 of the first support pattern 40 and the center axis Ca of the connection contact 30 is S2, and S1 has a size smaller by G than S2. Hence, in each first support pattern 40, the gap S1 between the top surface of the first tier support 41 and a center axis Ca of the connection contact 30 is smaller than the gap S2 between the top surface of the second tier support 42 and the center axis Ca of the connection contact 30. In each first support pattern 40, the top surface of the first tier support 41 may be disposed closer to the center axis Ca of the connection contact 30 by G than the top surface of the second tier support 42.

When the width of the connection contact 30 on a plane where the top surfaces of the first tier supports 41 are located is E and the width of the connection contact 30 on a plane where the top surfaces of the second tier supports 42 are located is F, G may have a size corresponding to half the difference between F and E.

The first support pattern 40 may be configured such that the first tier support 41 has a dimension larger than the second tier support 42. As illustrated in FIG. 2, in a direction away from the connection contact 30, the dimension of the top surface of the first tier support 41 of the first support pattern 40 is W11, the dimension of the top surface of the second tier support 42 of the first support pattern 40 is W12, and W11 may be larger than W12.

In each first support pattern 40, a center axis C11 of the first tier support 41 and a center axis C12 of the second tier support 42 may be offset from each other. In each first support pattern 40, the center axis C11 of the first tier support 41 may be disposed closer to the center axis Ca of the connection contact 30 than the center axis C12 of the second tier support 42. In each first support pattern 40, the center axis C11 of the first tier support 41 may be disposed at a location closer to the connection contact 30 by ΔS than the center axis C12 of the second tier support 42. By locating the center axis C11 of the first tier support 41 closer to the center axis Ca of the connection contact 30 than the center axis C12 of the second tier support 42, the difference between d1 and d2 may be increased.

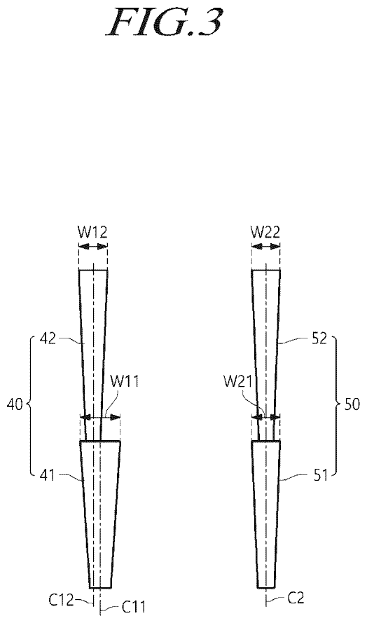

FIG. 3 is a diagram illustrating the first and second support patterns of FIG. 1.

Referring to FIG. 3, the first tier support 41 of the first support pattern 40 may have a dimension larger than the first tier support 51 of the second support pattern 50. As illustrated in FIG. 3, the dimension of the top surface of the first tier support 41 of the first support pattern 40 is W11, the dimension of the top surface of the first tier support 51 of the second support pattern 50 is W21, and W11 may be larger than W21.

The second tier support 42 of the first support pattern 40 may have substantially the same dimension as the second tier support 52 of the second support pattern 50. As illustrated in FIG. 3, the dimension of the top surface of the second tier support 42 of the first support pattern 40 is W12, the dimension of the top surface of the second tier support 52 of the second support pattern 50 is W22, and

W12 and W22 may be the same size.

In each second support pattern 50, the center axis of the first tier support 51 and the center axis of the second tier support 52 may be vertically aligned with each other. The center axis of the first tier support 51 and the center axis of the second tier support 52 may be positioned on a single line C2.

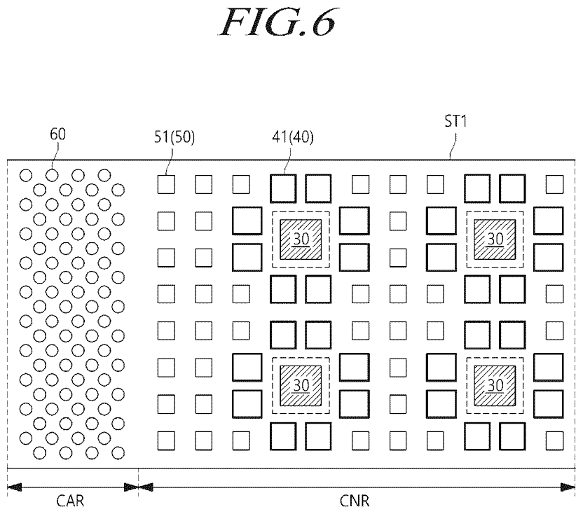

FIG. 4 is a plan view illustrating cell plugs and second tier supports of the first and second support patterns in the three-dimensional memory device according to an embodiment of the present disclosure, and FIGS. 5 and 6 are plan views illustrating cell plugs and first tier supports of the first and second support patterns in the three-dimensional memory device according to an embodiment of the present disclosure. FIG. 4 illustrates the planar structure of the upper surface of the second tier stack ST2, and FIGS. 5 and 6 illustrate the planar structures of the upper surface of the first tier stack ST1.

Referring to FIG. 4, a plurality of connection contacts 30 may be disposed in the connection region CNR. The second tier supports 42 and 52 of the first and second support patterns 40 and 50 may be disposed in the form of a matrix while forming a plurality of rows and a plurality of columns together with connection contacts 30 in the connection region CNR. The second tier supports 42 of the first support patterns 40 and the second tier supports 52 of the second support patterns 50 may have the same dimension. As illustrated in FIG. 4, a cross-sectional area of the second tier supports 42 and 52 may have a square shape. The cross-sectional area of the second tier supports 42 and 52 may be the same.

The plurality of cell plugs 60 may be disposed in a plurality of rows in the cell region CAR. Cell plugs 60 of odd-numbered rows and cell plugs 60 of even-numbered rows may be offset from each other. Due to this fact, a greater number of cell plugs 60 may be disposed within the same area.

Referring to FIG. 5, the first tier support 41 of the first support pattern 40 may have a dimension larger than the first tier support 51 of the second support pattern 50. In a direction away from the connection contact 30, the first tier support 41 of the first support pattern 40 may have a dimension larger than the first tier support 51 of the second support pattern 50.

The first tier support 41 of the first support pattern 40 may have a dimension in the direction away from the connection contact 30 larger than a dimension in a direction perpendicular to the direction away from the connection contact 30. In a plan view, the first tier support 41 of the first support pattern 40 may have a rectangular shape in which a long side extends in the direction away from the connection contact 30 and a short side extends in the direction perpendicular to the direction away from the connection contact 30. Alternatively, in another embodiment, in a plan view, the first tier support 41 of the first support pattern 40 may have an oval shape in which a major axis extends in the direction away from the connection contact 30 and a minor axis extends in the direction perpendicular to the direction away from the connection contact 30.

Referring again to FIGS. 4 and 5, the first tier support 41 of the first support pattern 40 may have a dimension larger than the second tier support 42 of the first support pattern 40. In the direction away from the connection contact 30, the first tier support 41 of the first support pattern 40 may have a dimension larger than the second tier support 42 of the first support pattern 40.

As the connection contact 30 has a tapered shape, the connection contact 30 has a smaller dimension on the upper surface of the first tier stack ST1 than on the upper surface of the second tier stack ST2. The region surrounded by the dotted line in FIG. 5 represents a portion corresponding to the connection contact 30 on the upper surface of the second tier stack ST2.

The gap between the first support patterns 40 which neighbor each other with the connection contact 30 interposed therebetween is larger than the gap between the first support pattern 40 and the second support pattern 50 which neighbor each other. The gap between the first support patterns 40 which neighbor each other with the connection contact 30 interposed therebetween is larger than the gap between second support patterns 50 which neighbor each other. When the gap between neighboring support patterns is larger than a predetermined size, a stack bending may occur, in which the gap between neighboring first and second interlayer insulating layers 22a and 22b (see FIG. 1) narrows or neighboring first and second interlayer insulating layers 22a and 22b (see FIG. 1) stick together. According to an embodiment of the present disclosure, by ensuring that the lower portion of the connection contact 30 has a dimension smaller than the upper portion of the connection contact 30, the gap between the first tier supports 41 of the first support patterns 40 which neighbor each other with the connection contact 30 interposed therebetween may be configured to have a size smaller than the gap between the second tier supports 42 of the first support patterns 40, by which it is possible to reduce the occurrence of a stack bending.

Referring to FIG. 6, the first tier support 41 of the first support pattern 40 may have a dimension larger than the first tier support 51 of the second support pattern 50 in the direction away from the connection contact 30 and the direction perpendicular to the direction away from the connection contact 30.

The first tier support 41 of the first support pattern 40 may have the same dimension in the direction away from the connection contact 30 and the direction perpendicular to the direction away from the connection contact 30. As illustrated in FIG. 6, in a plan view, the first tier support 41 of the first support pattern 40 may have a square shape. In another embodiment, in a plan view, the first tier support 41 of the first support pattern 40 may have a circular shape.

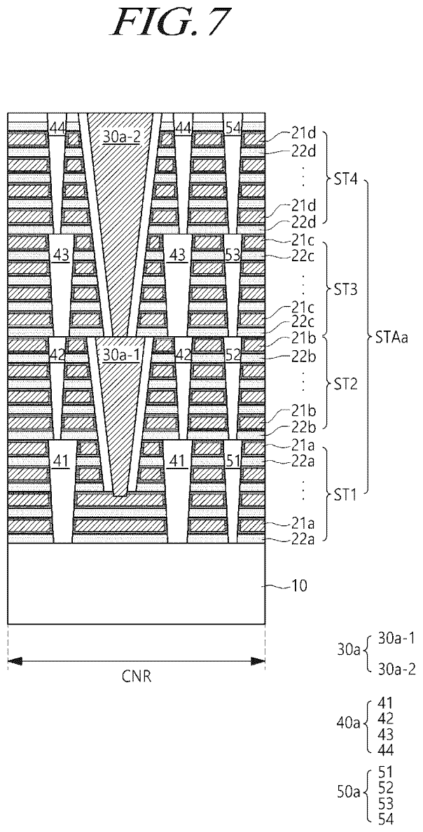

FIG. 7 is a cross-sectional view of a three-dimensional memory device according to an embodiment of the present disclosure.

Referring to FIG. 7, the three-dimensional memory device according to an embodiment of the present disclosure includes a stack structure STAa disposed on a substrate 10.

The stack structure STAa may include a first tier stack ST1 disposed on the substrate 10, a second tier stack ST2 disposed on the first tier stack ST1, a third tier stack ST3 disposed on the second tier stack ST2, and a fourth tier stack ST4 disposed on the third tier stack ST3.

The first tier stack ST1 may include a plurality of first electrode layers 21a and a plurality of first interlayer insulating layers 22a which are alternately stacked. As in the illustrated embodiment, the lowermost layer of the first stack ST1 may be a first interlayer insulating layer 22a and the uppermost layer of the first stack ST1 may be a first electrode layer 21a. Although not illustrated, each of the lowermost layer of the first stack and the uppermost layer of the first stack may be a first interlayer insulating layer. The second tier stack ST2 may include a plurality of second electrode layers 21b and a plurality of second interlayer insulating layers 22b which are alternately stacked. As in the illustrated embodiment, the lowermost layer of the second stack ST2 may be a second interlayer insulating layer 22b and the uppermost layer of the second stack ST2 may be a second electrode layer 21b. Although not illustrated, each of the lowermost layer of the second stack and the uppermost layer of the second stack may be a second interlayer insulating layer. The third tier stack ST3 may include a plurality of third electrode layers 21c and a plurality of third interlayer insulating layers 22c which are alternately stacked. As in the illustrated embodiment, the lowermost layer of the third stack ST3 may be a third interlayer insulating layer 22c and the uppermost layer of the third stack ST3 may be a third electrode layer 21c. Although not illustrated, each of the lowermost layer of the third stack and the uppermost layer of the third stack may be a third interlayer insulating layer. The fourth tier stack ST4 may include a plurality of fourth electrode layers 21d and a plurality of fourth interlayer insulating layers 22d which are alternately stacked. As in the illustrated embodiment, the lowermost layer of the forth stack ST4 may be a fourth interlayer insulating layer 22d and the uppermost layer of the fourth stack ST4 may be a fourth electrode layer 21d. Although not illustrated, each of the lowermost layer of the fourth stack and the uppermost layer of the fourth stack may be a fourth interlayer insulating layer.

The first, second, third and fourth electrode layers 21a, 21b, 21c and 21d may include a conductive material. For example, the first, second, third and fourth electrode layers 21a, 21b, 21c and 21d may include tungsten (W). As another example, the first, second, third and fourth interlayer insulating layers 22a, 22b, 22c and 22d may include silicon oxide.

A connection contact 30a may penetrate the stack structure STAa. The connection contact 30a may partially penetrate the stack structure STAa and be electrically connected to one of the first, second, third and fourth electrode layers 21a, 21b, 21c and 21d. For example, as illustrated in FIG. 7, the lower end of the connection contact 30a may be located on a first electrode layer 21a, and the connection contact 30a may be electrically connected to the first electrode layer 21a. Although not illustrated, the lower end of the connection contact 30a may be located on one of the second, third and fourth electrode layers 21b, 21c and 21d, and the connection contact 30a may be electrically connected to the one of the second, third and fourth electrode layers 21b, 21c and 21d. The connection contact 30a may serve to transmit an operating voltage from a row decoder (not illustrated), to one of the first, second, third and fourth electrode layers 21a, 21b, 21c and 21d. In an embodiment, although not illustrated, the connection contact 30a may be connected to one of the first, second, third and fourth electrode layers 21a, 21b, 21c and 21d while completely penetrating the stack structure STAa.

In another embodiment, although not illustrated, the connection contact 30a may not be electrically connected to the first, second, third and fourth electrode layers 21a, 21b, 21c and 21d of the stack structure STAa. The connection contact 30a may completely penetrate vertically the stack structure STAa, and may serve to electrically connect an upper interconnection (not illustrated) which is provided on the stack structure STAa and a lower interconnection (not illustrated) which is provided under the substrate 10.

The connection contact 30a may include a lower contact 30a-1 which penetrates the first and second tier stacks ST1 and ST2, and an upper contact 30a-2 which penetrates the third and fourth tier stacks ST3 and ST4 and is connected to the top surface of the lower contact 30a-1. Each of the lower contact 30a-1 and the upper contact 30a-2 has a tapered shape whose dimension (e.g., width, or cross-section area) decreases as a distance to the substrate 10 decreases.

Support patterns 40a (42, 42, 43, and 44) and 50a (51, 52, 53, and 54) may vertically penetrate the stack structure STAa. The support patterns 40a and 50a may include first support patterns 40a which neighbor the connection contact 30a and second support patterns 50a which do not neighbor the connection contact 30a.

The first support pattern 40a may include a first tier support 41 which penetrates the first tier stack ST1, a second tier support 42 which penetrates the second tier stack ST2, a third tier support 43 which penetrates the third tier stack ST3, and a fourth tier support 44 which penetrates the fourth tier stack ST4. The second support pattern 50a may include a first tier support 51 which penetrates the first tier stack ST1, a second tier support 52 which penetrates the second tier stack ST2, a third tier support 53 which penetrates the third tier stack ST3, and a fourth tier support 54 which penetrates the fourth tier stack ST4.

In each first support pattern 40a, the lower end of the first tier support 41 may be connected to the substrate 10, the lower end of the second tier support 42 may be connected to the first tier support 41, the lower end of the third tier support 43 may be connected to the second tier support 42, and the lower end of the fourth tier support 44 may be connected to the third tier support 43.

In each second support pattern 50a, the lower end of the first tier support 51 may be connected to the substrate 10, the lower end of the second tier support 52 may be connected to the first tier support 51, the lower end of the third tier support 53 may be connected to the second tier support 52, and the lower end of the fourth tier support 54 may be connected to the third tier support 53.

Each of the first, second, third and fourth tier supports 41, 42, 43 and 44 of the first support pattern 40a and the first, second, third and fourth tier supports 51, 52, 53 and 54 of the second support pattern 50a may have a tapered shape whose dimension (e.g., width or cross-section area) decreases as a distance to the substrate 10 decreases.

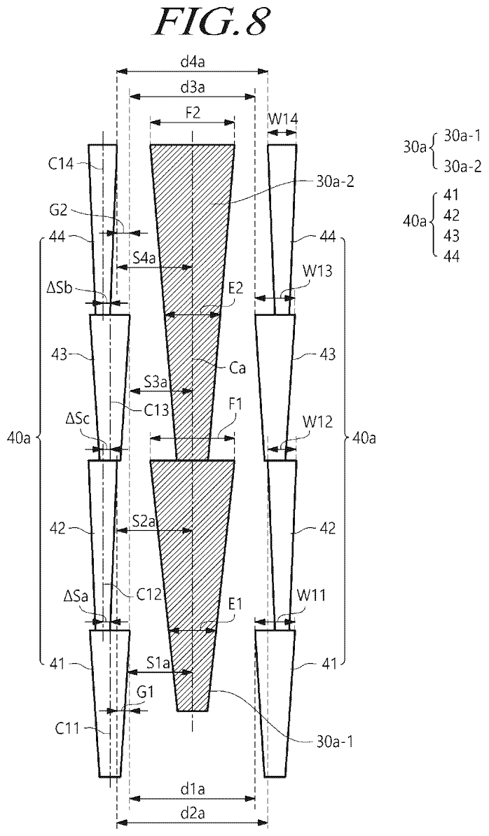

As will be described later with reference to FIG. 8, in two first support patterns 40a which neighbor each other with the connection contact 30a interposed therebetween, the gap between the first tier supports 41 has a size smaller than the gap between the second tier supports 42, and the gap between the third tier supports 43 has a size smaller than the gap between the fourth tier supports 44.

The connection contact 30a may be configured such that the lower end of the upper contact 30a-2 has a dimension smaller than the upper end of the lower contact 30a-1. Two first support patterns 40a which neighbor each other with the connection contact 30a interposed therebetween may be configured such that the gap between the third tier supports 43 has a size smaller than the gap between the second tier supports 42.

FIG. 8 is a diagram illustrating the connection contact and the first support patterns of FIG. 7.

Referring to FIG. 8, two first support patterns 40a which neighbor each other with the connection contact 30a interposed therebetween are configured such that the gap between the first tier supports 41 has a size smaller than the gap between the second tier supports 42 and the gap between the third tier supports 43 has a size smaller than the gap between the fourth tier supports 44.

In the two first support patterns 40a which neighbor each other with the connection contact 30a interposed therebetween, the gap between the top surfaces of the first tier supports 41 is d1a, the gap between the top surfaces of the second tier supports 42 are d2a, the gap between the top surfaces of the third tier supports 43 is d3a, the gap between the top surfaces of the fourth tier supports 44 is d4a, d1a is smaller than d2a, and d3a is smaller than d4a.

The first support pattern 40a is configured such that the gap between the top surface of the first tier support 41 and a center axis Ca of the connection contact 30a has a size smaller than the gap between the top surface of the second tier support 42 and the center axis Ca of the connection contact 30a. As illustrated in FIG. 8, the gap between the top surface of the first tier support 41 of the first support pattern 40a and the center axis Ca of the connection contact 30a is S1a, the gap between the top surface of the second tier support 42 of the first support pattern 40a and the center axis Ca of the connection contact 30a is S2a, and Sia may have a size smaller by G1 than S2a. In each first support pattern 40a, the top surface of the first tier support 41 may be disposed closer to the center axis Ca of the connection contact 30a by G1 than the top surface of the second tier support 42.

When the width of the connection contact 30a on a plane where the top surfaces of the first tier supports 41 are located is E1 and the width of the connection contact 30a on a plane where the top surfaces of the second tier supports 42 are located is F1, G1 may have a size corresponding to half the difference between F1 and E1.

The first support pattern 40a is configured such that the gap between the top surface of the third tier support 43 and the center axis Ca of the connection contact 30 has a size smaller than the gap between the top surface of the fourth tier support 44 and the center axis Ca of the connection contact 30. The gap between the top surface of the third tier support 43 of the first support pattern 40a and the center axis Ca of the connection contact 30a is S3a, the gap between the top surface of the fourth tier support 44 of the first support pattern 40a and the center axis Ca of the connection contact 30a is S4a, and S3a may have a size smaller by G2 than S4a. In each first support pattern 40a, the top surface of the third tier support 43 may be disposed closer to the center axis Ca of the connection contact 30a by G2 than the top surface of the fourth tier support 44.

When the width of the connection contact 30a on a plane where the top surfaces of the third tier supports 43 are located is E2 and the width of the connection contact 30a on a plane where the top surfaces of the fourth tier supports 44 are located is F2, G2 may have a size corresponding to half the difference between F2 and E2.

The first support pattern 40a may be configured such that the first tier support 41 has a dimension larger than the second tier support 42 and the third tier support 43 has a dimension larger than the fourth tier support 44. As illustrated in FIG. 8, the dimension of the top surface of the first tier support 41 of the first support pattern 40a is W11, the dimension of the top surface of the second tier support 42 of the first support pattern 40a is W12, the dimension of the top surface of the third tier support 43 of the first support pattern 40a is W13, the dimension of the top surface of the fourth tier support 44 of the first support pattern 40a is W14, W11 is larger than W12, and W13 is larger than W14.

Each first support pattern 40a may be configured such that a center axis C11 of the first tier support 41 and a center axis C12 of the second tier support 42 are offset from each other. In each first support pattern 40a, the center axis C11 of the first tier support 41 may be disposed at a location that is shifted by ΔSa toward the connection contact 30a from the center axis C12 of the second tier support 42. In each first support pattern 40a, the center axis C11 of the first tier support 41 may be located closer to the center axis Ca of the connection contact 30a by ΔSa than the center axis C12 of the second tier support 42.

By disposing the center axis C11 of the first tier support 41 closer to the connection contact 30a than the center axis C12 of the second tier support 42, the difference in size between d1a and d2a may be increased. That is, d1a may be configured to have a smaller size compared to d2a.

In each first support pattern 40a, a center axis C13 of the third tier support 43 and a center axis C14 of the fourth tier support 44 may be offset from each other. In each first support pattern 40a, the center axis C13 of the third tier support 43 may be disposed at a location that is shifted by ΔSb toward the connection contact 30a from the center axis C14 of the fourth tier support 44. In each first support pattern 40a, the center axis C13 of the third tier support 43 may be located closer to the center axis Ca of the connection contact 30a by ΔSb than the center axis C14 of the fourth tier support 44.

By disposing the center axis C13 of the third tier support 43 closer to the connection contact 30a than the center axis C14 of the fourth tier support 14, the difference in size between d3a and d4a may be increased. That is, d3a may be configured to have a smaller size compared to d4a.

The lower end of the upper contact 30a-2 may have a dimension smaller than the upper end of the lower contact 30a-1. Two first support patterns 40a which neighbor each other with the connection contact 30a interposed therebetween may be configured such that the gap between the third tier supports 43 has a size smaller than the gap between the second tier supports 42. As illustrated in FIG. 8, in the two first support patterns 40a which neighbor each other with the connection contact 30a interposed therebetween, the gap d3a between the top surfaces of the third tier supports 43 is smaller than the gap d2a between the top surfaces of the second tier supports 42.

In each first support pattern 40a, the third tier support 43 may have a dimension larger than the second tier support 42. As illustrated in FIG. 8, the dimension W13 of the top surface of the third tier support 43 of the first support pattern 40a may be larger than the dimension W12 of the top surface of the second tier support 42 of the first support pattern 40a.

In each first support pattern 40a, the center axis C13 of the third tier support 43 and the center axis C12 of the second tier support 42 may be offset from each other. In each first support pattern 40a, the center axis C13 of the third tier support 43 may be disposed at a location that is shifted by ΔSc toward the connection contact 30a from the center axis C12 of the second tier support 42. In each first support pattern 40a, the center axis C13 of the third tier support 43 may be located closer to the center axis Ca of the connection contact 30a by ΔSc than the center axis C12 of the second tier support 42.

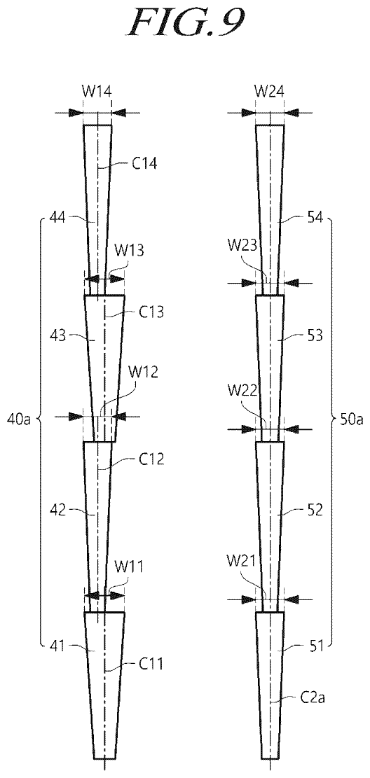

FIG. 9 is a diagram illustrating the first and second support patterns of FIG. 7.

Referring to FIG. 9, the first tier support 41 of the first support pattern 40a may have a dimension larger than the first tier support 51 of the second support pattern 50a. The third tier support 43 of the first support pattern 40a may have a dimension larger than the third tier support 53 of the second support pattern 50a. As illustrated in FIG. 9, the dimension of the top surface of the first tier support 41 of the first support pattern 40a is W11, the dimension of the top surface of the first tier support 51 of the second support pattern 50a is W21, and W11 may be larger than W21. The dimension of the top surface of the third tier support 43 of the first support pattern 40a is W13, the dimension of the top surface of the third tier support 53 of the second support pattern 50a is W23, and W13 may be larger than W23.

The second tier support 42 of the first support pattern 40a may have substantially the same dimension as the second tier support 52 of the second support pattern 50a. The fourth tier support 44 of the first support pattern 40a may have substantially the same dimension as the fourth tier support 54 of the second support pattern 50a. As illustrated in FIG. 9, the dimension of the top surface of the second tier support 42 of the first support pattern 40a is W12, the dimension of the top surface of the second tier support 52 of the second support pattern 50a is W22, and W12 and W22 may have substantially the same size. The dimension of the top surface of the fourth tier support 44 of the first support pattern 40a is W14, the dimension of the top surface of the fourth tier support 54 of the second support pattern 50a is W24, and W14 and W24 may have substantially the same size.

In each second support pattern 50a, the center axis of the first tier support 51, the center axis of the second tier support 52, the center axis of the third tier support 53 and the center axis of the fourth tier support 54 may be vertically aligned with each other. As illustrated in FIG. 9, in the second support pattern 50a, the center axis of the first tier support 51, the center axis of the second tier support 52, the center axis of the third tier support 53 and the center axis of the fourth tier support 54 may be located on a single line C2a.

According to an embodiment of the present disclosure, by ensuring that the lower portion of the lower contact 30a-1 of the connection contact 30a has a dimension smaller than the upper portion and the lower portion of the upper contact 30a-2 of the connection contact 30a has a dimension smaller than the upper portion, the gap between the first tier supports 41 of first support patterns 40a which neighbor each other with the connection contact 30a interposed therebetween may be configured to have a size smaller than the gap between the second tier supports 42 of the first support patterns 40a, and the gap between the third tier supports 43 of the first support patterns 40a may be configured to have a size smaller than the gap between the fourth tier supports 44 of the first support patterns 40a, whereby it is possible to reduce the occurrence of a stack bending.

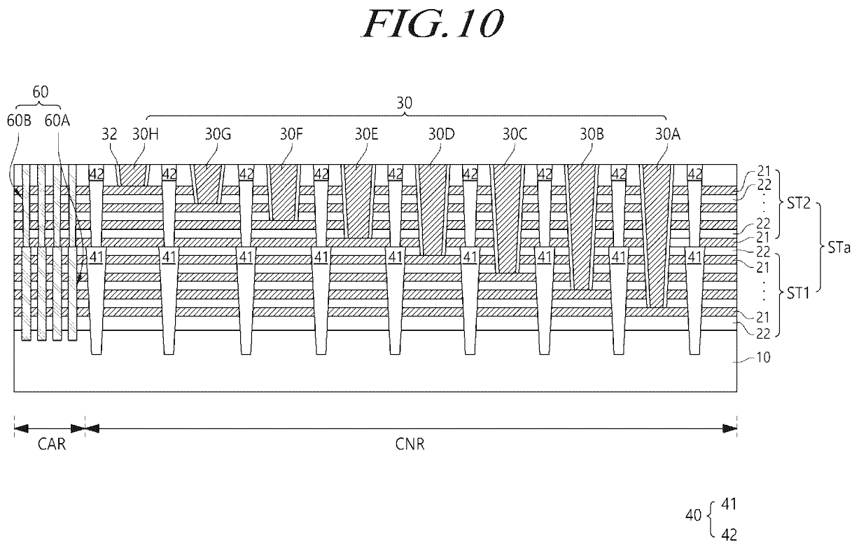

FIG. 10 is a cross-sectional view illustrating a three-dimensional memory device according to an embodiment of the present disclosure.

Referring to FIG. 10, a substrate 10 may include a cell region CAR and a connection region CNR which extends from the cell region CAR. The cell region CAR and the connection region CNR are adjacent to each other.

A stack structure STa may be disposed on the cell region CAR and the connection region CNR of the substrate 10. The stack structure STa may include a first tier stack ST1 disposed on the substrate 10 and a second tier stack ST2 disposed on the first tier stack ST1.

Each of the first and second tier stacks ST1 and ST2 may include a plurality of electrode layers 21 and a plurality of interlayer insulating layers 22 which are alternately stacked with an insulating layer being a lowermost layer of the stack structure STa. The plurality of electrode layers 21 may include word lines, a drain select line and a source select line.

A plurality of cell plugs 60 may be disposed in the cell region CAR.

The plurality of cell plugs 60 may vertically penetrate the stack structure STa to extend to the substrate 10. Each cell plug 60 may include a first portion 60A which vertically penetrates the first tier stack ST1 and a second portion 60B which vertically penetrates the second tier stack ST2. Each of the first portion 60A of the cell plug 60 and the second portion 60B of the cell plug 60 may have a tapered shape whose dimension decreases as a distance to the substrate 10 decreases. Each second portion 60B is connected to a corresponding first portion 60A and a lowermost end of the second portion is smaller in dimension than an uppermost end of the corresponding first portion 60A.

A plurality of connection contacts 30A, 30B, 30C, 30D, 30E, 30F, 30G and 30H: 30 may be disposed in the connection region CNR. The plurality of connection contacts 30 may penetrate the stack structure STa at different depths to be connected to corresponding electrode layers 21, respectively. Each of the plurality of the connection contacts 30 may be disposed between two adjacent first support patterns 40.

Each of the connection contacts 30 has a tapered shape whose dimension decreases as a distance to the substrate 10 decreases. A sidewall insulating layer 32 may be disposed on the side surfaces of the connection contacts 30 to electrically separate the connection contacts 30 and the electrode layers 21 of the stack structure Sta so that each connection contact is electrically connected at a lowermost end thereof with only one corresponding electrode layer 21.

A plurality of first support patterns 40 may be disposed in the connection region CNR. The first support patterns 40 may vertically penetrate the stack structure STa. Each of the first support patterns 40 may neighbor at least one of the plurality of connection contacts 30. FIG. 10 illustrates that one first support pattern 40 is disposed between two neighboring connection contacts 30, but the embodiments of the present disclosure are not limited thereto. At least two first support patterns 40 may be disposed between two neighboring connection contacts 30.

Each of the first support patterns 40 may include a first tier support 41 which penetrates the first tier stack ST1 and a second tier support 42 which penetrates the second tier stack ST2. The lower end of the first tier support 41 may be connected to the substrate 10, and the lower end of the second tier support 42 may be connected to the first tier support 41.

Each of the first and second tier supports 41 and 42 may have a tapered shape whose dimension decreases as a distance to the substrate 10 decreases.

As described above with reference to FIG. 2, two first support patterns 40 which neighbor each other with the connection contact 30 interposed therebetween may be configured such that the gap between the first tier supports 41 has a size smaller than the gap between the second tier supports 42.

As described above with reference to FIG. 5, the first support pattern 40 may be configured such that the first tier support 41 has a dimension larger than the second tier support 42.

For example, in a direction away from the connection contact 30, the dimension of the top surface of the first tier support 41 of the first support pattern 40 may be larger than the dimension of the top surface of the second tier support 42 of the first support pattern 40. In a direction perpendicular to the direction away from the connection contact 30, the dimension of the top surface of the first tier support 41 of the first support pattern 40 may have substantially the same size as the dimension of the top surface of the second tier support 42 of the first support pattern 40. For example, in a plan view, the first tier support 41 of the first support pattern 40 may have a rectangular or oval shape.

For another example, in the direction away from the connection contact 30 and the direction perpendicular to the direction away from the connection contact 30, the first tier support 41 of the first support pattern 40 may have a dimension larger than the second tier support 42 of the first support pattern 40. For example, in a plan view, the first tier support 41 of the first support pattern 40 may have a square or circular shape.

According to an embodiment of the present disclosure, by ensuring that the lower portion of each of the connection contacts 30 has a dimension smaller than the upper portion, the gap between the first tier supports 41 of first support patterns 40 which neighbor each other with the connection contact 30 interposed therebetween may be configured to have a size smaller than the gap between the second tier supports 42 of the first support patterns 40, whereby it is possible to reduce a stack bending in a region where the connection contacts 30 which are connected to the electrode layers 21 are disposed. Hereinafter, a method of fabricating a three-dimensional memory device according to an embodiment of the present disclosure will be described.

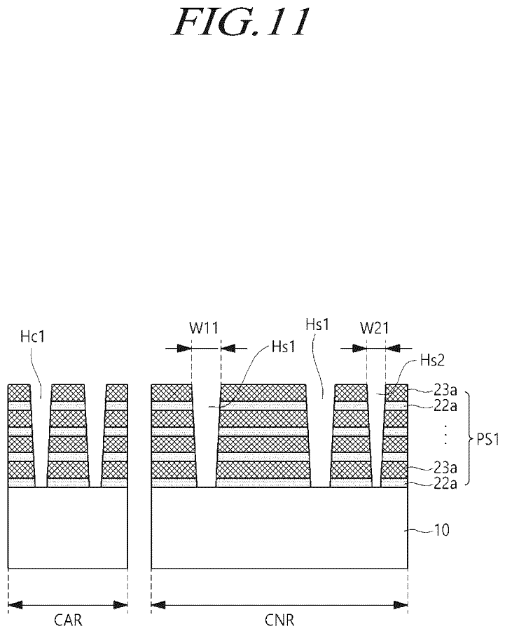

FIGS. 11 to 16 are views showing a method of fabricating a three-dimensional memory device according to an embodiment of the present disclosure.

Referring to FIG. 11, an operation of forming a first pre-stack PS1 on a substrate 10 and forming first channel holes Hc1 and first and second holes Hs1 and Hs2 in the first pre-stack PS1 is performed.

The first pre-stack PS1 is formed by alternately stacking a plurality of first interlayer insulating layers 22a and a plurality of first sacrificial layers 23a. The first interlayer insulating layers 22a may include silicon oxide. The first sacrificial layers 23a may include a material which has a different etch selectivity with respect to the first interlayer insulating layers 22a, for example, nitride such as silicon nitride.

The first channel holes Hc1 and the first and second holes Hs1 and Hs2 are formed by etching the first pre-stack PS1 through a photolithography process. The first channel holes Hc1 may vertically penetrate a cell region CAR of the first pre-stack PS1, and the first and second holes Hs1 and Hs2 may vertically penetrate a connection region CNR of the first pre-stack PS1.

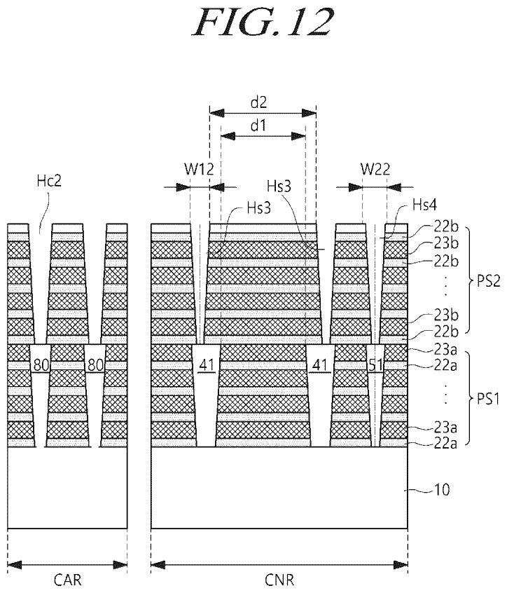

The first channel holes Hc1 provide, together with second channel holes Hc2 to be described below with reference to FIG. 12, spaces for disposing cell plugs (60 of FIG. 1). The first hole Hs1 provides a space for disposing a first tier support (41 of FIG. 1) of a first support pattern (40 of FIG. 1), and the second hole Hs2 provides a space for disposing a first tier support (51 of FIG. 1) of a second support pattern (50 of FIG. 1). The first hole Hs1 has a dimension larger than the second hole Hs2. The upper end of the first hole Hs1 has a dimension of W11, the upper end of the second hole Hs2 has a dimension of W21, and W11 is larger than W21.

Referring to FIG. 12, an operation of forming first gap fill sacrificial patterns 80 and first tier supports 41 and 51, forming a second pre-stack PS2 and forming a plurality of second channel holes Hc2 and a plurality of third and fourth holes Hs3 and Hs4 in the second pre-stack PS2 is performed.

The first gap fill sacrificial patterns 80 and the first tier supports 41 and 51 are formed by forming a gap fill material to fill the first channel holes Hc1 (see FIG. 11) and the first and second holes Hs1 and Hs2 (see FIG. 11) and then removing the gap fill material which is formed outside the first channel holes Hc1 (see FIG. 11) and the first and second holes Hs1 and Hs2 (see FIG. 11). The gap fill material may be made of an insulating material which has an etch selectivity different from those of the first interlayer insulating layers 22a and the first sacrificial layers 23a.

The second pre-stack PS2 may be formed by alternately stacking a plurality of second interlayer insulating layers 22b and a plurality of second sacrificial layers 23b on the first pre-stack PS1, the first gap fill sacrificial patterns 80 and the first tier supports 41 and 51. The second interlayer insulating layers 22b may include silicon oxide. The second sacrificial layers 23b may include a material which has a different etch selectivity with respect to the second interlayer insulating layers 22b, for example, nitride such as silicon nitride.

The second channel holes Hc2 and the third and fourth holes Hs3 and Hs4 may be formed by etching the second pre-stack PS2 through a photolithography process. The second channel holes Hc2 are formed to vertically penetrate the cell region CAR of the second pre-stack PS2 to expose the first gap fill sacrificial patterns 80, respectively. The third holes Hs3 are formed to vertically penetrate the connection region CNR of the second pre-stack PS2 to expose the first tier supports 41, respectively. The fourth holes Hs4 are formed to vertically penetrate the connection region CNR of the second pre-stack PS2 to expose the first tier supports 51, respectively.

Each third hole Hs3 provides a space for disposing a second tier support (42 of FIG. 1) of the first support pattern (40 of FIG. 1), and the fourth hole Hs4 provides a space for disposing a second tier support (52 of FIG. 1) of the second support pattern (50 of FIG. 1).

The third holes Hs3 are formed such that a gap d2 between the third holes Hs3 has a size larger than a gap d1 between the first tier supports 41 of the first support patterns (40 of FIG. 1). The third hole Hs3 may have a dimension smaller than the first hole Hs1 (see FIG. 11). The fourth hole Hs4 may have substantially the same dimension as the third hole Hs3. The upper end of the third hole Hs3 has a dimension of W12 which is smaller than a dimension W11 (see FIG. 11) of the upper end of the first hole Hs1 (see FIG. 11). The upper end of the fourth hole Hs4 has a dimension of W22, and W22 may have the same size as W12.

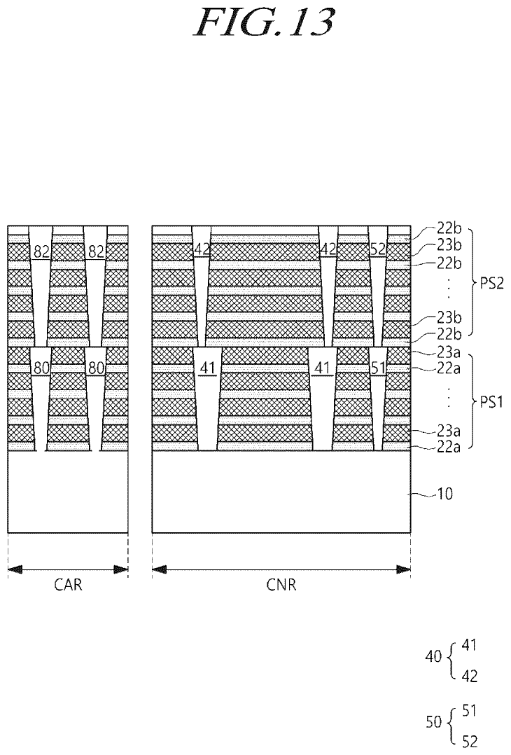

Referring to FIG. 13, an operation of forming second gap fill sacrificial patterns 82 and second tier supports 42 and 52 is performed.

The second gap fill sacrificial patterns 82 and the second tier supports 42 and 52 are formed by forming a gap fill material to fill the second channel holes Hc2 (see FIG. 12) and the third and fourth holes Hs3 and Hs4 (see FIG. 12) and then removing the gap fill material which is formed outside the second channel holes Hc2 (see FIG. 12) and the third and fourth holes Hs3 and Hs4 (see FIG. 12). The gap fill material may be made of an insulating material which has an etch selectivity different from those of the first and second interlayer insulating layers 22a and 22b and the first and second sacrificial layers 23a and 23b.

As a result, a first support pattern 40 in which the first and second tier supports 41 and 42 are stacked is formed, and a second support pattern 50 in which the first and second tier supports 51 and 52 are stacked is formed.

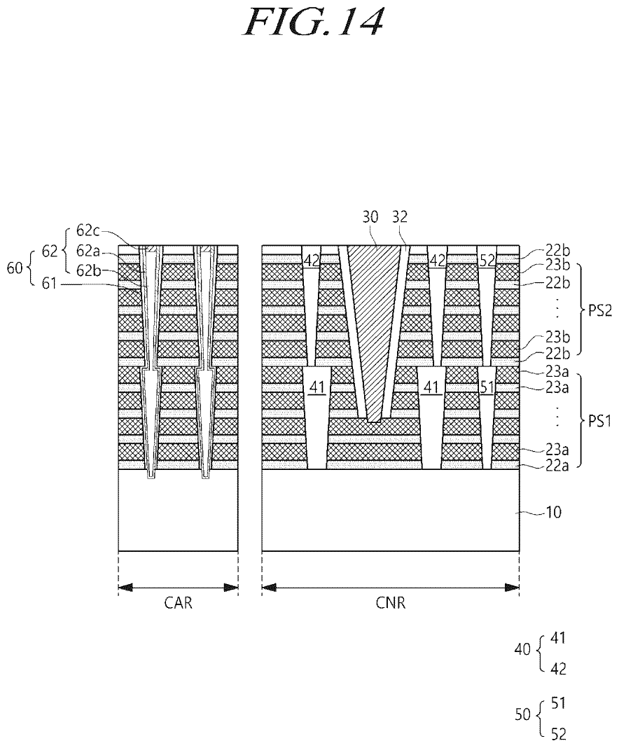

Referring to FIG. 14, an operation of forming a plurality of cell plugs 60 and a connection contact 30 is performed.

By removing the first and second gap fill sacrificial patterns 80 and 82 (see FIG. 13) and forming a memory layer 61 and a channel layer 62 in the spaces created due to the removal of the first and second gap fill sacrificial patterns 80 and 82 (see FIG. 13), the plurality of cell plugs 60 are formed.

By forming, between the first support patterns 40, a hole penetrating the first and second pre-stacks PS1 and PS2, forming a sidewall insulating layer 32 on the sidewall of the hole and then filling the inside of the hole with a conductive material, the connection contact 30 is formed.

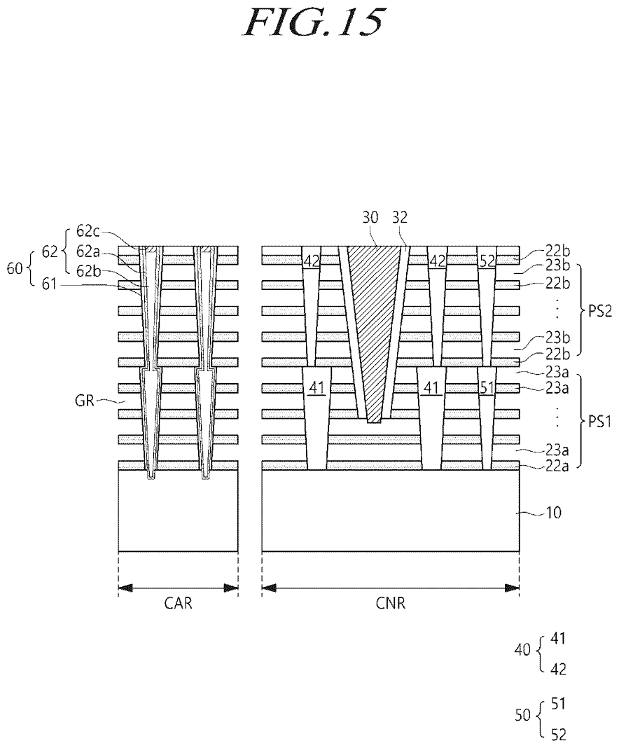

Referring to FIG. 15, an operation of selectively removing the first and second sacrificial layers 23a and 23b is performed.

As the first and second sacrificial layers 23a and 23b are removed, a plurality of electrode regions GR may be opened. The electrode regions GR may be provided between the first and second interlayer insulating layers 22a and 22b which vertically neighbor each other.

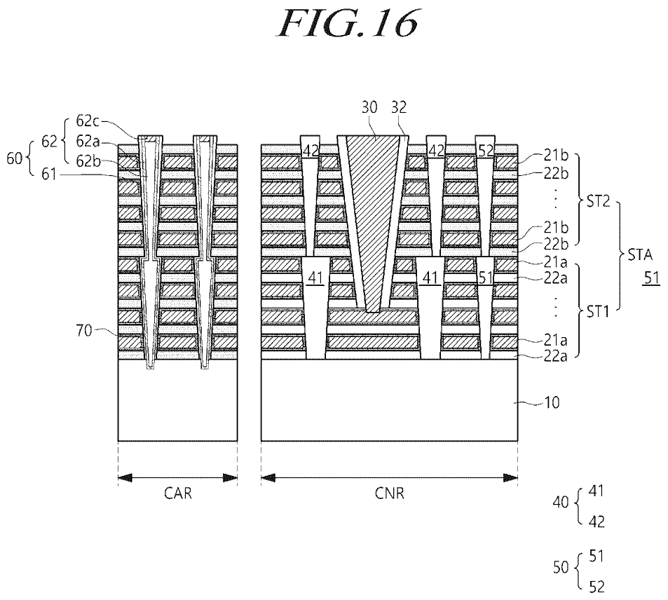

Referring to FIG. 16, an operation of forming a second blocking insulating layer 70 and first and second electrode layers 21a and 21b is performed.

The second blocking insulating layer 70 is formed along the surfaces of the electrode regions GR. The first and second electrode layers 21a and 21b are formed by filling the electrode regions GR with a conductive material.

Although specific embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. Furthermore, the embodiments may be combined to form additional embodiments.

What is claimed is:

1. A three-dimensional memory device comprising:
a stack structure including first and second tier stacks stacked on a substrate, each of the first and second tier stacks including a plurality of electrode layers and a plurality of interlayer insulating layers alternately stacked;
a connection contact penetrating at least partially the stack structure; and
a plurality of support patterns each including a first tier support penetrating the first tier stack and a second tier support penetrating the second tier stack,
wherein the plurality of support patterns include first support patterns adjacent to the connection contact, and
wherein in two first support patterns among the first support patterns, which neighbor each other with the connection contact interposed therebetween, a gap between first tier supports is smaller than a gap between second tier supports.

2. The three-dimensional memory device according to claim 1, wherein in each of the first support patterns, a top surface of the first tier support is spaced apart from a center axis of the connection contact by a first gap, and a top surface of the second tier support is spaced from the center axis of the connection contact by a second gap larger than the first gap.

3. The three-dimensional memory device according to claim 2, wherein a difference between the first gap and the second gap is half a difference between a width of the connection contact on a plane where top surfaces of first tier supports of the first support patterns are located and a width of the connection contact on a plane where top surfaces of second tier supports of the first support patterns are located.

4. The three-dimensional memory device according to claim 1, wherein in each of the first support patterns, the first tier support has a dimension larger than the second tier support.

5. The three-dimensional memory device according to claim 1, wherein in each of the first support patterns, a top surface of the first tier support has a dimension larger than a top surface of the second tier support in a direction away from the connection contact.

6. The three-dimensional memory device according to claim 1, wherein in each of first tier supports of the first support patterns, in a plan view a dimension in a direction away from the connection contact is larger than a dimension in a direction perpendicular to the direction away from the connection contact.

7. The three-dimensional memory device according to claim 1, wherein each of first tier supports of the first support patterns has a rectangular, oval, square or circular shape in a plan view.

8. The three-dimensional memory device according to claim 1, wherein in each of the first support patterns, a center axis of the first tier support and a center axis of the second tier support are offset from each other.

9. The three-dimensional memory device according to claim 1, wherein the connection contact has a tapered shape whose dimension decreases as a distance to the substrate decreases.

10. The three-dimensional memory device according to claim 1, wherein
the plurality of support patterns further include a second support pattern which does not neighbor the connection contact, and
one of first tier supports of the first support patterns has a dimension larger than a first tier support of the second support pattern.

11. The three-dimensional memory device according to claim 1, further comprising:
a cell plug penetrating the stack structure,
wherein the cell plug has a step portion whose width changes discontinuously at a boundary between the first tier stack and the second tier stack.

12. A three-dimensional memory device comprising:
a stack structure including first, second, third and fourth tier stacks which are stacked on a substrate and each of which includes a plurality of electrode layers and a plurality of interlayer insulating layers alternately stacked;
a connection contact including a lower contact which penetrates the first and second tier stacks and an upper contact which penetrates the third and fourth tier stacks to be connected to the lower contact; and
a plurality of support patterns each including a first tier support which penetrates the first tier stack, a second tier support which penetrates the second tier stack, a third tier support which penetrates the third tier stack, and a fourth tier support which penetrates the fourth tier stack,
wherein the plurality of support patterns include first support patterns which neighbor the connection contact, and
wherein in two first support patterns among the first support patterns, which neighbor each other with the connection contact interposed therebetween, a gap between first tier supports is smaller than a gap between second tier supports, and a gap between third tier supports is smaller than a gap between fourth tier supports.

13. The three-dimensional memory device according to claim 12, wherein
in each of the first support patterns,
a top surface of the first tier support and a center axis of the connection contact are spaced apart from each other by a first gap, and a top surface of the second tier support and the center axis of the connection contact are spaced apart from each other by a second gap larger than the first gap, and
a top surface of the third tier support and the center axis of the connection contact are spaced apart from each other by a third gap, and a top surface of the fourth tier support and the center axis of the connection contact are spaced apart from each other by a fourth gap larger than the third gap.

14. The three-dimensional memory device according to claim 13, wherein a difference between the first gap and the second gap is half a difference between a width of the connection contact on a plane where top surfaces of first tier supports of the first support patterns are located and a width of the connection contact on a plane where top surfaces of second tier supports of the first support patterns are located.

15. The three-dimensional memory device according to claim 13, wherein a difference between the third gap and the fourth gap is half a difference between a width of the connection contact on a plane where top surfaces of third tier supports of the first support patterns are located and a width of the connection contact on a plane where top surfaces of fourth tier supports of the first support patterns are located.

16. The three-dimensional memory device according to claim 12, wherein the first tier support has a dimension larger than the second tier support, and the third tier support has a dimension larger than the fourth tier support.

17. The three-dimensional memory device according to claim 12, wherein in each of first and third tier supports of the first support patterns, in a plan view, a dimension in a direction away from the connection contact is larger than a dimension in a direction perpendicular to the direction away from the connection contact.

18. The three-dimensional memory device according to claim 12, wherein in each of the first support patterns, a top surface of the first tier support has a dimension larger than a top surface of the second tier support in a direction away from the connection contact, and a top surface of the third tier support has a dimension larger than a top surface of the fourth tier support in the direction away from the connection contact.

19. The three-dimensional memory device according to claim 12, wherein in each of the first support patterns, a center axis of the first tier support and a center axis of the second tier support are offset from each other, and a center axis of the third tier support and a center axis of the fourth tier support are offset from each other.

20. The three-dimensional memory device according to claim 12, wherein each of the lower contact and the upper contact has a tapered shape whose dimension decreases as a distance to the substrate decreases.

21. The three-dimensional memory device according to claim 12, wherein
the plurality of support patterns further include a second support pattern which does not neighbor the connection contact, and,
each of first tier supports of the first support patterns has a dimension larger than the first tier support of the second support pattern, and each of third tier supports of the first support patterns has a dimension larger than the third tier support of the second support pattern.

22. The three-dimensional memory device according to claim 12, wherein
a dimension of a bottom portion of the upper contact is smaller than a dimension of a top surface of the lower contact, and
in two first support patterns among the first support patterns, which neighbor each other with the connection contact interposed therebetween, a gap between third tier supports is smaller than a gap between second tier supports.

23. The three-dimensional memory device according to claim 22, wherein in each of the first support patterns, a gap between a top surface of the third tier support and a center axis of the connection contact is smaller than a gap between a top surface of the second tier support and the center axis of the connection contact.

24. The three-dimensional memory device according to claim 22, wherein in each of the first support patterns, the third tier support has a dimension larger than the second tier support.

25. The three-dimensional memory device according to claim 22, wherein in each of the first support patterns, a top surface of the third tier support has a dimension larger than a top surface of the second tier support in a direction away from the connection contact.

26. The three-dimensional memory device according to claim 22, wherein in each of the first support patterns, a center axis of the second tier support and a center axis of the third tier support are offset from each other.

27. A three-dimensional memory device comprising:
a substrate having a cell region and a connection region which extends from the cell region;
a stack structure including first and second tier stacks which are stacked on the substrate and each of which includes a plurality of interlayer insulating layers and a plurality of electrode layers alternately stacked;
a plurality of connection contacts extending to the plurality of electrode layers, respectively, by penetrating the connection region of the stack structure; and
a plurality of support patterns penetrating the connection region of the stack structure, and each including a first tier support which penetrates the first tier stack and a second tier support which penetrates the second tier stack,
wherein in two support patterns among the plurality of support patterns, which neighbor each other with one of the plurality of connection contacts interposed therebetween, a gap between first tier supports is smaller than a gap between second tier supports.

28. The three-dimensional memory device according to claim 27, wherein in each of the plurality of support patterns, the first tier support has a dimension larger than the second tier support.

29. The three-dimensional memory device according to claim 27, wherein in each of the plurality of support patterns, a top surface of the first tier support has a dimension larger than a top surface of the second tier support in a direction away from the connection contact.

30. The three-dimensional memory device according to claim 27, wherein in each of first tier supports of the support patterns, in a plan view, a dimension in a direction away from the connection contact is larger than a dimension in a direction perpendicular to the direction away from the connection contact.

31. The three-dimensional memory device according to claim 27, wherein each of first tier supports of the support patterns has a rectangular, oval, square or circular shape in a plan view.

32. The three-dimensional memory device according to claim 27, wherein each of the plurality of connection contacts has a tapered shape whose dimension decreases as a distance to the substrate decreases.
